(19) United States
(12) Patent Application Publication
(10) Pub. No.: US 2025/0259968 A1
(43) Pub. Date: Aug. 14, 2025

(54) SEMICONDUCTOR MODULE AND VEHICLE

(71) Applicant: FUJI ELECTRIC CO., LTD., Kawasaki-shi (JP)

(72) Inventor: Tomoya HIRATA, Kawasaki-shi (JP)

(73) Assignee: FUJI ELECTRIC CO., LTD., Kawasaki-shi (JP)

(21) Appl. No.: 19/006,472

(22) Filed: Dec. 31, 2024

(30) Foreign Application Priority Data
Feb. 9, 2024 (JP) 2024-018488

(51) Int. Cl. H01L 25/065; H01L 23/00; H01L 23/049; H01L 23/373; H01L 25/18; H02P 27/06

(52) U.S. Cl. CPC H01L 25/0655; H01L 23/049; H01L 23/3735; H01L 24/48; H01L 25/18; H01L 2224/48137; H01L 2224/48225; H01L 2924/1203; H01L 2924/13055; H01L 2924/19107; H01L 2924/30107; H02P 27/06

(57) ABSTRACT

A semiconductor module, including: a wiring board having first and second conductor patterns; a plurality of semiconductor elements disposed on the first conductor pattern; first and second bonding members connecting first and second main electrodes of the semiconductor elements to the first and second conductor patterns, respectively; first and second terminals connected to the first and second main electrodes of the semiconductor elements through the first and second conductor patterns, respectively; and a third terminal connected to the second conductor pattern through a plurality of third bonding members. A distance between a connection point of each of the third bonding members to the second conductor pattern and a connection point of the second bonding member to the second conductor pattern varies depending on a distance between a predetermined position and a connection point of the second bonding member to the second main electrode of each semiconductor element.

### CROSS-REFERENCE TO RELATED APPLICATION

This application is based upon and claims the benefit of priority to Japanese Patent Application No. 2024-018488, filed on Feb. 9, 2024, the entire contents of which are incorporated herein by reference.

### BACKGROUND OF THE INVENTION

### 1. Technical Field

The present invention relates to a semiconductor module and a vehicle.

### 2. Description of the Related Art

A semiconductor module used in a power conversion apparatus includes a plurality of insulated gate bipolar transistor (IGBT) elements connected in parallel. In this type of semiconductor module, there is provided a conductive member that is referred to as an auxiliary emitter for connecting an emitter of an IGBT element to a gate drive circuit connected to gates of a plurality of IGBT elements connected in parallel (for example, JP 2023-167403 A, WO 2020/054806 A, WO 2022/059251 A, and WO 2022/264851 A).

### SUMMARY OF THE INVENTION

In the semiconductor module including the auxiliary emitter, the non-uniform switching operation in each of the plurality of IGBT elements connected in parallel causes variation in heat generation of each IGBT element, and the reliability of the semiconductor module may deteriorate.

An object of the present invention is to reduce variations in switching operation among a plurality of switching elements connected in parallel in a semiconductor module.

A semiconductor module according to one aspect includes: a wiring board having a first conductor pattern and a second conductor pattern disposed on one surface of an insulating substrate; a plurality of semiconductor elements disposed on the first conductor pattern of the wiring board; a first bonding member for connecting each of first main electrodes of the plurality of semiconductor elements to the first conductor pattern; a second bonding member for connecting each of second main electrodes of the plurality of semiconductor elements to the second conductor pattern; a first terminal connected to the first main electrodes of the plurality of semiconductor elements through the first conductor pattern, through which a main current flows; a second terminal connected to the second main electrodes of the plurality of semiconductor elements through the second conductor pattern, through which a main current flows; and a third terminal connected to the second conductor pattern through a third bonding member. Each of the plurality of semiconductor elements includes a switching element that controls a current flowing between the first main electrode and the second main electrode. The third bonding member includes a plurality of bonding members associated with each of the plurality of semiconductor elements. The distance from a connection point of the plurality of bonding members on the second conductor pattern to a connection point of the second bonding member varies depending on the distance from a predetermined position in the third terminal to a connection point with the second bonding member in the second main electrode of the plurality of semiconductor elements.

According to the above-described aspect, it is possible to reduce variations in switching operation among the plurality of switching elements connected in parallel in the semiconductor module.

### BRIEF DESCRIPTION OF THE DRAWINGS

FIG. 1 is a plan view of a semiconductor module according to an embodiment;

FIG. 2 is a cross-sectional view for illustrating a configuration example in a case of the semiconductor module of FIG. 1;

FIG. 3 is a partially enlarged cross-sectional view for illustrating a configuration example of an auxiliary emitter wiring in the semiconductor module of FIG. 1;

FIG. 4 is an equivalent circuit diagram of an inverter circuit formed in the semiconductor module of FIG. 1;

FIG. 5A is an equivalent circuit diagram for illustrating an example of inductances of the auxiliary emitter wiring in the semiconductor module according to the embodiment, and FIG. 5B is a graph illustrating an example of a switching operation in the semiconductor module according to the embodiment;

FIG. 6 is a partially enlarged plan view for illustrating a conventional example of the auxiliary emitter wiring in a semiconductor module in which a plurality of semiconductor elements is connected in parallel;

FIG. 7A is an equivalent circuit diagram for illustrating an example of the inductance of the auxiliary emitter wiring in the semiconductor module of FIG. 6, and FIG. 7B is a graph illustrating an example of a switching operation in the semiconductor module of FIG. 6;

FIG. 8 is a partially enlarged plan view for illustrating a modification of the semiconductor module according to the embodiment; and

FIG. 9 is a schematic plan view for illustrating an example of a vehicle to which the semiconductor module according to the present invention is applied.

### DETAILED DESCRIPTION

Hereinafter, an embodiment of the present invention will be described in detail with reference to the drawings. A “semiconductor module” in the following description is obtained by sealing semiconductor elements, which are referred to as semiconductor chips, dies, or the like, with an insulating material. The semiconductor module may be referred to as a “semiconductor device” or the like.

An X axis, a Y axis, and a Z axis in each of the drawings to be referred to are illustrated for the purpose of defining a plane and a direction in the illustrated semiconductor module. The X axis, the Y axis, and the Z axis are perpendicular to each other and form a right-handed system. In the following description, a direction parallel to the X axis is referred to as an X direction, a direction parallel to the Y axis is referred to as a Y direction, and a direction parallel to the Z axis is referred to as a Z direction. Also, in a case where each of the X direction, the Y direction, and the Z direction is associated with a direction of an arrow (positive or negative) of the X axis, the Y axis, and the Z axis illustrated, a “positive side” or a “negative side” is added.

In the present specification, the Z direction may be referred to as a vertical direction. In the present specification, “on” and “upper side” are intended to be on the positive side in the Z direction with respect to the reference surface, member, position, and the like, and “below” and “lower side” are intended to be on the negative side in the Z direction with respect to the reference surface, member, position, and the like. For example, when it is described that “the member B is disposed on the member A”, the member B is disposed on the positive side in the Z direction as viewed from the member A. Also, when the term “upper surface of the member A” is described, the surface includes a surface that is positioned at the end of the member A on the positive side in the Z direction and faces the positive side in the Z direction. These directions and surfaces associated with the directions are words used for convenience of description, and a correspondence relationship with the directions of the X axis, the Y axis, and the Z axis may change depending on the mounting posture of the semiconductor module and the like. For example, in the present specification, a surface of a semiconductor element facing a wiring board is referred to as a lower surface, and a surface opposite to the lower surface is referred to as an upper surface, but the terms are not limited thereto, and the surface facing the wiring board may be referred to as the upper surface, and the surface opposite thereto may be referred to as the lower surface.

An aspect ratio and a magnitude relationship between respective members in each drawing are merely schematically represented, and do not necessarily coincide with a relationship in a semiconductor module actually manufactured. For convenience of description, it is also assumed that a magnitude relationship between respective members is exaggeratedly expressed, or an expression is different from an outer shape of a member used in an actual semiconductor module. Also, for convenience of description, some of the cross-sectional views illustrate a cross-sectional configuration of the semiconductor module cut along a virtual cutting line that is not able to be accurately illustrated in the plan view.

The descriptions of “not illustrated”, “not shown” and the like in the present specification are intended not to clearly indicate, by use of a specific reference sign and a leader line, which portion of the drawing is a component to which the descriptions are given. For example, a “first main electrode not illustrated” is intended to mean both that a portion representing the first main electrode (for example, a shape, a line, or the like) is not illustrated in the drawing, and that there is neither a reference sign nor a leader line clearly indicating a portion corresponding to the first main electrode in the drawing. Also, the underlined reference sign in the drawing indicates a whole component that encompasses a plurality of portions distinguished by a plurality of reference signs.

A semiconductor module to be illustrated in the following description may be applied to, for example, a power conversion apparatus such as an inverter apparatus of industrial or electrical equipment (for example, an in-vehicle motor). Thus, in the following description, a detailed description of the same or similar configuration, function, operation, manufacturing method, and the like as or to those of a known semiconductor module will be skipped.

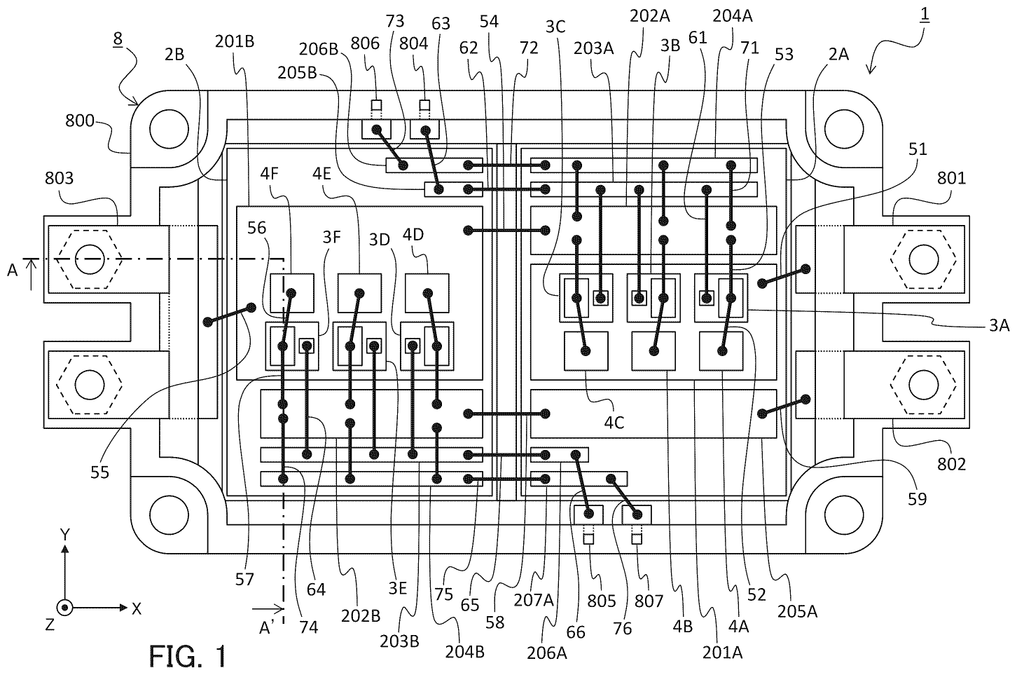

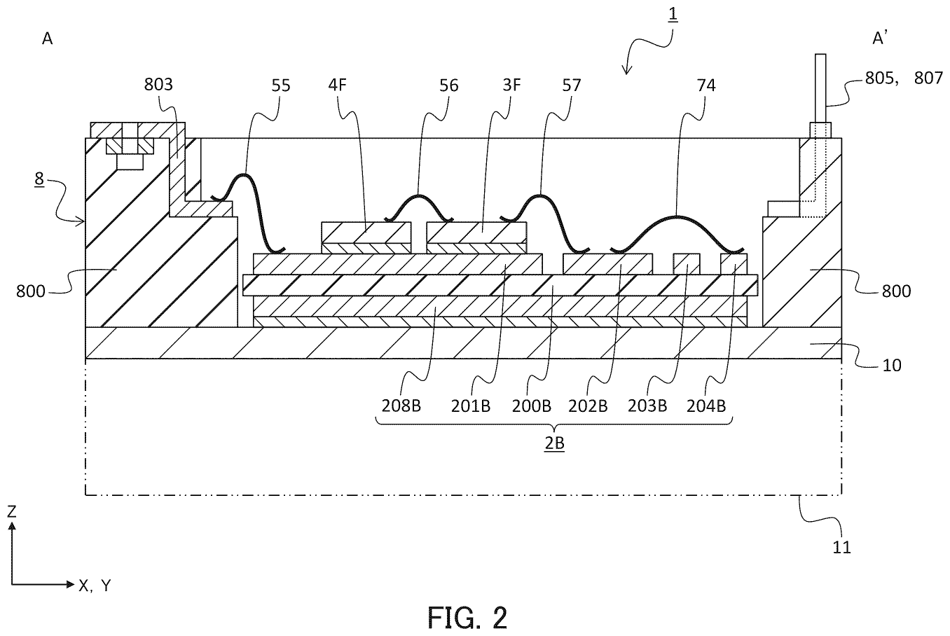

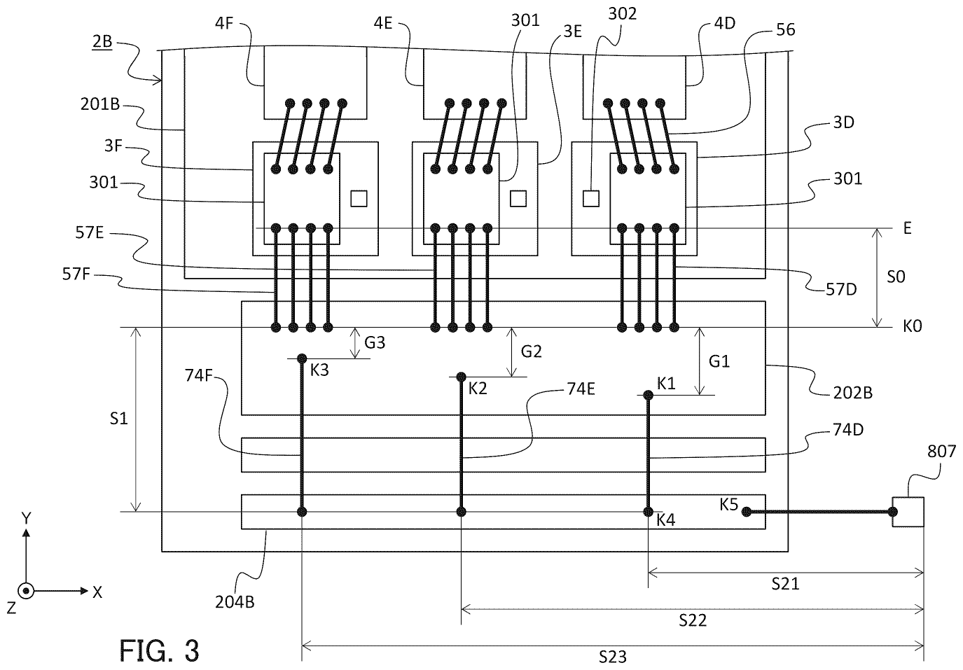

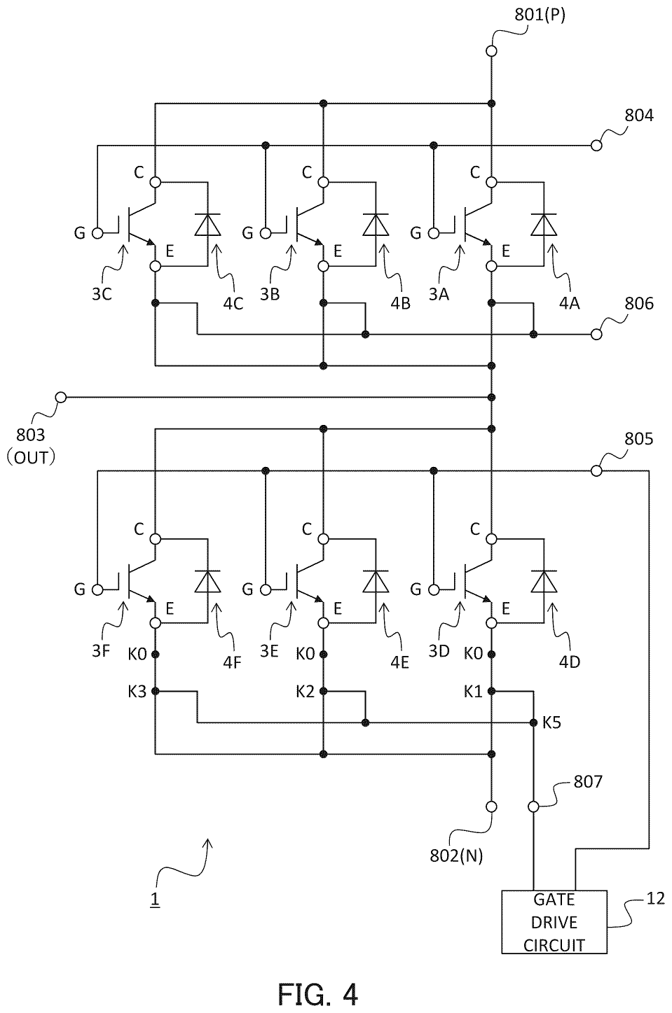

FIG. 1 is a plan view of a semiconductor module according to an embodiment. FIG. 2 is a cross-sectional view for illustrating a configuration example in a case of the semiconductor module of FIG. 1. FIG. 3 is a partially enlarged cross-sectional view for illustrating a configuration example of the auxiliary emitter wiring in the semiconductor module of FIG. 1. FIG. 4 is an equivalent circuit diagram of an inverter circuit formed in the semiconductor module of FIG. 1. The cross-sectional view of FIG. 2 may be an example of a cross-sectional configuration of the semiconductor module I cut along an alternate long and short dash line A-A′ in a semiconductor module 1 of FIG. 1.

The semiconductor module 1 according to the present embodiment includes wiring boards 2A and 2B, semiconductor elements 3A to 3F, and 4A to 4F, bonding members 51 to 59, 61 to 66, and 71 to 76, a case 8, a scaling material (not shown), and heat sink 10. In the present specification, in a case where a plurality of identical components is distinguished, a reference sign represented by combination of a number and an alphabet following the number is described, and in a case where a plurality of identical components is not distinguished, a reference sign represented by only the number is described. For example, when a specific semiconductor element among the plurality of semiconductor elements 3A to 3F is designated, the reference sign (any one of 3A to 3F) assigned to the specific semiconductor element is described in FIG. 1, and in other cases, the semiconductor element is simply described as “semiconductor element 3”.

The wiring board 2 is an element-mounted component on which the semiconductor elements 3 and 4, which are sometimes referred to as semiconductor chips, dies, or the like, arc mounted. The semiconductor element 3 is a switching element such as an insulated gate bipolar transistor (IGBT) element, and the semiconductor element 4 is a diode such as a free wheeling diode (FWD) element. The wiring board 2, the semiconductor element 3, and the semiconductor element 4 are circuit components for forming a half-bridge inverter circuit illustrated in FIG. 4.

The wiring board 2A includes an insulating substrate 200A, conductor patterns 201A to 207A disposed on the upper surface of the insulating substrate 200A, and a heat dissipation pattern 208A disposed on the lower surface of insulating substrate 200A. The wiring board 2B includes an insulating substrate 200B, conductor patterns 201B to 206B disposed on the upper surface of insulating substrate 200B, and a heat dissipation pattern 208B disposed on the lower surface of insulating substrate 200B. The wiring board 2 may be a direct copper bonding (DCB) substrate or an active metal brazing (AMB) substrate, but is not limited thereto.

The insulating substrate 200 may be, for example, a ceramic substrate made of a ceramic material such as aluminum oxide (Al₂O₃), aluminum nitride (AlN), silicon nitride (Si₃N₄), or a composite material of aluminum oxide (Al₂O₃) and zirconium oxide (ZrO₂). The insulating substrate 200 may be a substrate obtained by molding an insulating resin such as epoxy resin into a sheet shape, a substrate obtained by impregnating a base material such as a glass fiber with an insulating resin, a substrate obtained by coating a surface of a flat plate-shaped metal core with an insulating resin, or the like.

These conductor patterns 201 to 207 disposed on the upper surface of the insulating substrate 200 are used as wiring in an electronic circuit such as an inverter circuit formed in the semiconductor module 1. The heat dissipation pattern 208 disposed on the lower surface of insulating substrate 200 is used as a thermally conductive material that conducts heat generated by the semiconductor element 3 during operation of semiconductor module 1 to heat sink 10. These conductor patterns 201 to 207 and the heat dissipation pattern 208 are formed of, for example, metal plates, metal foils, or the like such as copper or aluminum.

The wiring board 2 is disposed on the upper surface of the heat sink 10 together with case 8. The case 8 includes a frame-shaped insulating member 800 having open ends on the upper surface and the lower surface thereof, and a plurality of terminals 801 to 807 integrated with the insulating member 800. When being disposed on the upper surface of the heat sink 10, the insulating member 800 of the case 8 may have a shape in which a space is defined that houses the wiring board 2, the semiconductor element 3, the semiconductor element 4, the bonding members 5, 6, 7, and the like, and that may be filled with a scaling material for scaling them. The wiring board 2A and the wiring board 2B may be integrated. The heat dissipation pattern 208 of the wiring board 2 is connected to be in close contact with the upper surface of the heat sink 10 by a bonding material such as solder (not illustrated) or a thermally conductive material such as thermal grease or thermal compound. The heat sink 10 may be, for example, a metal plate such as copper or aluminum. A plurality of fins may be provided on the lower surface of the heat sink 10. The heat sink 10 may be a portion of a cooler 11 or a component connected to the cooler 11. That is, the cooler 11 is any component in the semiconductor module 1 of the present embodiment.

The terminals 801 to 807 of the case 8 are roughly divided into main terminals 801 to 803 and control terminals 804 to 807. The main terminals 801 to 803 are connected to an electrode through which a main current flows in a switching element such as an IGBT element. In the case of the semiconductor module 1 in which the inverter circuit illustrated in FIG. 4 is formed, a first main terminal 801 is a P-IN terminal connected to the positive electrode of a DC power supply, and is connected to the collector electrode of the semiconductor element (IGBT element) 3 disposed on the upper surface of the wiring board 2A. A second main terminal 802 is an N-IN terminal connected to the negative electrode of the DC power supply, and is connected to the emitter electrode of the semiconductor element (IGBT chip) 3 disposed on the upper surface of the wiring board 2B. A third main terminal 803 is an OUT terminal connected to a load consuming alternating current converted from direct current by the semiconductor module 1, and is connected to the emitter electrode of the semiconductor element 3 disposed on the upper surface of the wiring board 2A and the collector electrode of the semiconductor element 3 disposed on the upper surface of the wiring board 2B. A control terminal 804 is connected to a gate electrode of the semiconductor element 3 disposed on the upper surface of the wiring board 2A, and a control terminal 805 is connected to a gate electrode of the semiconductor element 3 disposed on the upper surface of the wiring board 2B. A control terminal 806 is connected to the emitter electrode of the semiconductor element 3 disposed on the upper surface of the wiring board 2A, and a control terminal 807 is connected to the emitter electrode of the semiconductor element 3 disposed on the upper surface of the wiring board 2B. The control terminals 806 and 807 are terminals for connecting the emitter electrode of the semiconductor element 3 to a gate drive circuit 12 (see FIG. 4) connected to the gate electrode of the semiconductor element 3, and are referred to as an auxiliary emitter terminal, a sense emitter terminal, an emitter sense terminal, or the like. The gate drive circuit 12 is a circuit that generates a control signal for controlling on/off of the switching element of the semiconductor element 3 using the emitter potential input through the control terminals 806 and 807 as a ground, and applies the control signal to the gate electrode of the semiconductor element 3. Control signals for the semiconductor elements 3A to 3C disposed on the upper surface of the wiring board 2A are generated based on the potential of the control terminal 806, and control signals for the semiconductor elements 3D to 3F disposed on the upper surface of the wiring board 2B are generated based on the potential of the control terminal 807. The gate drive circuit connected to the gate electrodes of the semiconductor elements 3A to 3C, and the gate drive circuit connected to the gate electrodes of the semiconductor elements 3D to 3E may be formed in separate elements or may be formed in a single element. These terminals 801 to 807 are integrally formed with the insulating member 800, and have an outer terminal portion extending to the outside of the semiconductor module 1 and an inner terminal portion exposed to a space in which the wiring board 2 and the like are disposed.

On the upper surface of the wiring board 2A, there are disposed semiconductor elements 3A to 3C, which are switching elements, and semiconductor elements 4A to 4C, which are diodes. As illustrated in FIG. 4, the semiconductor elements 3A to 3C are connected in parallel between the first main terminal 801 and the third main terminal 803 of the case 8, and the semiconductor elements 4A to 4C are connected in anti-parallel to the semiconductor elements 3A to 3C.

The semiconductor elements 3A to 3C are disposed on the conductor pattern 201A of the wiring board 2A in a direction in which a surface provided with the collector electrode is the lower surface and another surface provided with the emitter electrode and the gate electrode is the upper surface, and the collector electrode and the conductor pattern 201A are bonded by a bonding material (not shown) such as solder. In this case, the semiconductor elements 4A to 4C arc disposed on the conductor pattern 201A in a direction in which a surface provided with a cathode electrode is the lower surface and another surface provided with an anode electrode is the upper surface, and the cathode electrode and the conductor pattern 201A are bonded by a bonding material (not shown) such as solder. The bonding material for bonding the collector electrode of the semiconductor element 3 and the conductor pattern 201 is an example of a first bonding member for connecting the first main electrode of the semiconductor element 3 and a first conductor pattern of the wiring board 2.

The conductor pattern 201A of the wiring board 2A is connected to the first main terminal 801 by a bonding member 51. Emitter electrodes of the semiconductor elements 3A to 3C are respectively connected to anode electrodes of the semiconductor elements 4A to 4C by a bonding member 52, and connected to a conductor pattern 202A of the wiring board 2A by a bonding member 53. The conductor pattern 202A is connected to the third main terminal 803 through a bonding member 54, the conductor pattern 201B of the wiring board 2B, and a bonding member 55. The gate electrodes of the semiconductor elements 3A to 3C are connected to the conductor pattern 203A of the wiring board 2A by a bonding member 61. The conductor pattern 203A is connected to the control terminal 804 through a bonding member 62, the conductor pattern 205B of the wiring board 2B, and a bonding member 63. Also, the conductor pattern 202A of the wiring board 2A is connected to the conductor pattern 204A of the wiring board 2A by a bonding member 71. The conductor pattern 204A is connected to the control terminal (auxiliary emitter terminal) 806 through a bonding member 72, the conductor pattern 206B of the wiring board 2B, and a bonding member 73. The bonding member 53 for connecting the emitter electrode of the semiconductor element 3 and the conductor pattern 202 is an example of a second bonding member for connecting the second main electrode of the semiconductor element 3 and the second conductor pattern of the wiring board 2. The bonding member 71 for connecting the conductor pattern 202 and the conductor pattern 204 of the wiring board 2 is an example of a third bonding member for connecting the second conductor pattern of the wiring board 2 to a third terminal.

On the upper surface of the wiring board 2B, there are disposed semiconductor elements 3D to 3F, which are switching elements, and semiconductor elements 4D to 4F, which are diodes. As illustrated in FIG. 4, the semiconductor elements 3D to 3F are connected in parallel between the third main terminal 803 and the second main terminal 802 of the case 8, and the semiconductor elements 4D to 4F are connected in anti-parallel to the semiconductor elements 3D to 3F.

The semiconductor elements 3D to 3F are disposed on the conductor pattern 201B of the wiring board 2B in a direction in which a surface provided with the collector electrode is the lower surface and another surface provided with an emitter electrode 301 and a gate electrode 302 is the upper surface (see FIG. 3), and the collector electrode and the conductor pattern 201B are bonded by a bonding material (not shown) such as solder. In this case, the semiconductor elements 4D to 4F are disposed on the conductor pattern 201B in a direction in which a surface provided with a cathode electrode is the lower surface and another surface provided with an anode electrode is the upper surface, and the cathode electrode and the conductor pattern 201B are bonded by a bonding material (not shown) such as solder.

The conductor pattern 201B of the wiring board 2B is connected to the third main terminal 803 by the bonding member 55. The emitter electrode 301 of each of the semiconductor elements 3D to 3F is connected to the anode electrode of each of the semiconductor elements 4A to 4C by a bonding member 56, and is connected to the conductor pattern 202B of the wiring board 2B by a bonding member 57. The conductor pattern 202B is connected to the second main terminal 802 through a bonding member 58, the conductor pattern 205A of the wiring board 2A, and a bonding member 59. Each of the gate electrodes 302 of semiconductor elements 3D to 3F is connected to the conductor pattern 203B of the wiring board 2B by a bonding member 64. The conductor pattern 203B is connected to the control terminal 805 through a bonding member 65, the conductor pattern 206A of the wiring board 2A, and a bonding member 66. Also, the conductor pattern 202B of the wiring board 2B is connected to the conductor pattern 204B of the wiring board 2B by a bonding member 74. The conductor pattern 204B is connected to the control terminal (auxiliary emitter terminal) 807 through a bonding member 75, the conductor pattern 207A of the wiring board 2A, and a bonding member 76.

The bonding members 51 to 59, the bonding members 61 to 66, and the bonding members 71 to 76 of the semiconductor module 1 may be bonding wires (metal thin wires). In the following description, the bonding members 51 to 59, the bonding members 61 to 66, and the bonding members 71 to 76 are also referred to as bonding wires 51 to 59, bonding wires 61 to 66, and bonding wires 71 to 76. For example, in the semiconductor module 1, as illustrated in FIG. 3, the emitter electrode 301 of each semiconductor element 3 is connected to the anode electrode of the semiconductor element 4 by four bonding wires 56, and is connected to the conductor pattern 202B of the wiring board 2B by four bonding wires 57. Also, in the semiconductor module 1 of the present embodiment, the conductor pattern 202B and the conductor pattern 204B connected to the control terminal (auxiliary emitter terminal) 807 are connected by separate bonding wires 74D to 74F for each emitter electrode 301 of semiconductor elements 3D to 3F connected in parallel. Furthermore, in the semiconductor module 1 of the present embodiment, the length of a wiring section common to the path of the main current in the auxiliary emitter wiring is changed depending on the length of the auxiliary emitter wiring from different emitter electrode 301 in each of the semiconductor elements 3D to 3F to the control terminal (auxiliary emitter terminal) 807. Specifically, as illustrated in FIG. 3, the longer the auxiliary emitter wiring is, the shorter the wiring section common to the path of the main current is. Note that FIG. 3 illustrates only the auxiliary emitter wiring for the semiconductor elements 3D to 3F connected in parallel between the third main terminal 803 and the second main terminal 802. The auxiliary emitter wiring for the semiconductor elements 3A to 3C connected in parallel between the first main terminal 801 and the third main terminal 803 may have the same configuration as the auxiliary emitter wiring for the semiconductor elements 3D to 3F.

The length of the auxiliary emitter wiring is represented by the sum of the length of the bonding wire 57 for connecting the emitter electrode 301 of the semiconductor element 3 and the conductor pattern 202B of the wiring board 2B, the length of the bonding wire 74 for connecting the conductor pattern 202B and the conductor pattern 204B, the distance from the connection point of the bonding wire 57 on the conductor pattern 202B to the connection point of the bonding wire 74, and the distance from the connection point of the bonding wire 57 on the conductor pattern 204B to the control terminal 807.

In the example of FIG. 3, lengths S0 of the bonding wires 57D to 57F connected to each emitter electrode 301 of the semiconductor elements 3D to 3E are substantially the same, and distances S1 from the connection point K0 of the bonding wires 57D to 57F on the conductor pattern 202B side to the connection point K4 of the bonding wires 74D to 74F on the conductor pattern 204B side in the plan view are substantially the same. The “connection point” in the present specification is intended to be a representative point in a region where the conductor pattern of the wiring board 2 and the third bonding member are connected. Also, in the example of FIG. 3, a magnitude relationship among a distance S21 from the connection point K4 of the bonding wire 74D on the side of the conductor pattern 204B to the control terminal 807, a distance S22 from the connection point K4 of the bonding wire 74E on the side of the conductor pattern 204B to the control terminal 807, and a distance S23 from the connection point K4 of the bonding wire 74F on the side of the conductor pattern 204B to the control terminal 807 is a relationship of S23>S22>S21. In such a case, as illustrated in FIG. 3, a magnitude relationship among a distance G1 from the connection point K0 of the bonding wire 57D to the connection point K1 of the bonding wire 74D on the conductor pattern 202B, a distance G2 from the connection point K0 of the bonding wire 57E to the connection point K2 of the bonding wire 74E, and a distance G3 from the connection point K0 of the bonding wire 57F to the connection point K3 of the bonding wire 74F should be a relationship of G3<G2<G1. In this way, for example, in the auxiliary emitter wiring of the semiconductor elements 3D to 3F connected in parallel, voltage drops in sections from the connection point K5 of the bonding wire 75 in the conductor pattern 204B of the wiring board 2B to the emitter electrode 301 may be easily made uniform.

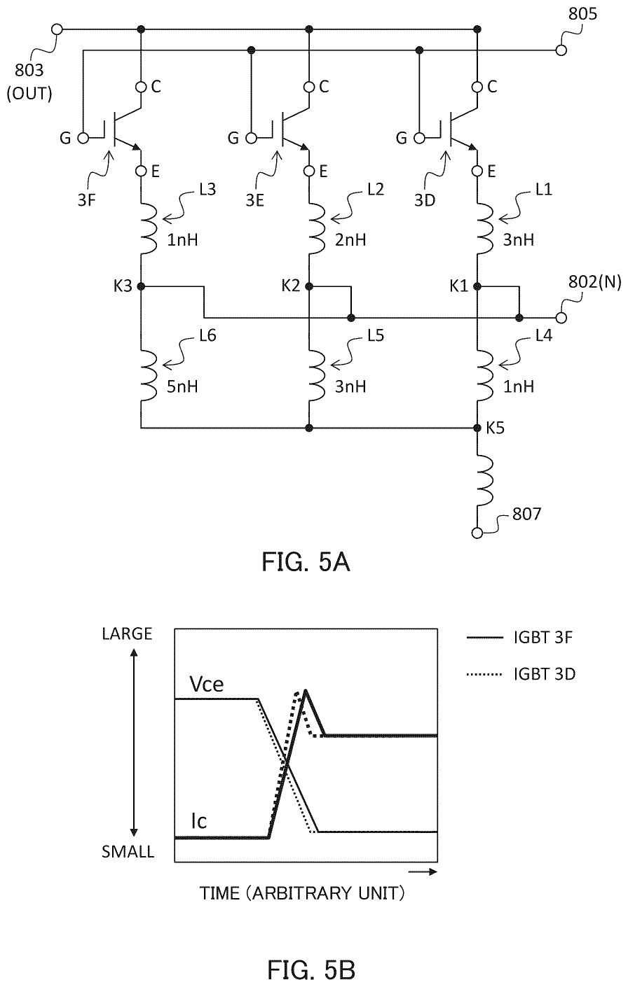

FIG. 5A is an equivalent circuit diagram for illustrating an example of the inductances of the auxiliary emitter wiring in the semiconductor module according to the embodiment, and FIG. 5B is a graph illustrating an example of a switching operation in the semiconductor module according to the embodiment.

When focusing on inductances, the auxiliary emitter wiring for the switching elements (semiconductor elements) 3D to 3F in the semiconductor module 1 described above with reference to FIGS. 1 to 4 may be represented as the equivalent circuit diagram of FIG. 5A. In FIG. 5A, a white circle (○) with “E” corresponds to the connection point E between the emitter electrode 301 of the semiconductor elements 3D to 3F and each of the bonding wires 57D to 57F as illustrated in FIG. 3. Also, the connection points K1 to K3 and the connection point K5 in FIG. 5A correspond to the connection points K1 to K3 and the connection point K5 in FIG. 3.

In the circuit diagram of FIG. 5A, the magnitude relationship among an inductance L1 in the section from the connection point E of the switching element 3D to the connection point K1, an inductance L2 in the section from the connection point E of the switching element 3E to the connection point K2, and an inductance L3 in the section from the connection point E of the switching element 3F to the connection point K3 coincides with the magnitude relationship of the lengths of each section in the auxiliary emitter wiring, and is the relationship of L3<L2<L1. Similarly, the magnitude relationship of inductances L4 to L6 in sections from the connection points K1 to K3 to the connection point K5 coincides with the magnitude relationship of the lengths of each section in the auxiliary emitter wiring, and is the relationship of L6>L5>L4. On the other hand, the magnitude relationship of the inductances of the entire auxiliary emitter wiring is (L3+L6)>(L2+L5)>(L1+L4), but the main current and the temporal change of the main current are larger than a current flowing through a single section (section where no main current flows) in the auxiliary emitter wiring so that the influences of the inductances L1, L2, and L3 are larger than those of the inductances L4, L5, and L6 when viewed in terms of the voltage drop. Therefore, by adjusting the position of the connection point of the bonding wires 74D to 74F with the conductor pattern 202B of the wiring board 2B and the position of the connection point of the bonding wires 74D to 74F with the conductor pattern 204B, voltage drops of the auxiliary emitter wiring with respect to each of the switching elements 3D to 3F may be easily made uniform.

Also, voltage drops across the auxiliary emitter wiring for each of the switching elements 3D to 3F are made uniform, thereby reducing variations in the switching speed, the switching loss, and the like among the switching elements 3D to 3F connected in parallel. For example, FIG. 5B schematically illustrates waveforms of the collector current Ic and the collector-emitter voltage Vce during the turn-on of the semiconductor elements 3D and 3F, which are associated with the switching speed and the switching loss in the conventional configuration. In the semiconductor module 1 of the present embodiment, a difference between the waveform of the collector current Ic of the semiconductor element 3D and the waveform of the collector current Ic of the semiconductor element 3F, and a difference between the waveform of the collector-emitter voltage Vce of the semiconductor element 3D and the waveform of the collector-emitter voltage Vce of the semiconductor element 3F are smaller than differences as illustrated in FIG. 5B. Also, the waveform of the collector current Ic and the waveform of the collector-emitter voltage Vce of the semiconductor element 3E have smaller differences from the waveform of the collector current Ic and the waveform of the collector-emitter voltage Vce of the semiconductor elements 3D and 3F. That is, in the semiconductor module 1 of the present embodiment, variations in heat generation among the switching elements (semiconductor elements) 3D to 3F may be suppressed, and the reliability of the semiconductor module 1 may be improved.

For example, in the semiconductor devices (semiconductor modules) of WO 2022/059251 A and WO 2022/264851 A, the conductor pattern, which is a part of the auxiliary emitter wiring corresponding to the conductor pattern 204B and through which no main current flows, and the emitter electrode of the semiconductor element are directly connected by a bonding wire as illustrated in FIG. 3. That is, in the semiconductor devices of WO 2022/059251 A and WO 2022/264851 A, the auxiliary emitter wiring does not include a section where the main current flows. In such a semiconductor device, for example, variations such as inductances L4 to L6 in the section where no main current flows as illustrated in FIG. 5A, occur in the inductance of the auxiliary emitter wiring with respect to each of the semiconductor elements connected in parallel. Therefore, voltage drops across the auxiliary emitter wiring vary. That is, in the semiconductor devices of WO 2022/059251 A and WO 2022/264851 A, voltage drops across the auxiliary emitter wiring for each of the semiconductor elements connected in parallel may not be made uniform using inductances in sections where the main current flows as in the semiconductor module 1 of the present embodiment. Therefore, in the semiconductor devices of WO 2022/059251 A and WO 2022/264851 A, it is difficult to reduce variations in the switching speed, the switching loss, and the like among the semiconductor elements connected in parallel.

Also, in the semiconductor device (semiconductor module) of JP 2023-167403 A, the conductor pattern 202B and the conductor pattern corresponding to the conductor pattern 204B are connected by one bonding wire as illustrated in FIG. 3. In such a semiconductor device, for example, variations such as inductances L1 to L3 in sections where the main current flows as illustrated in FIG. 5A, occur, resulting in variations in the voltage drop. That is, in the semiconductor device of JP 2023-167403 A, voltage drops across the auxiliary emitter wiring for each of the semiconductor elements connected in parallel may not be made uniform using the combination of inductances in sections where the main current flows and inductances in sections where no main current flows as in the semiconductor module 1 of the present embodiment. Therefore, in the semiconductor device of JP 2023-167403 A, it is difficult to reduce variations in the switching speed, the switching loss, and the like among semiconductor elements connected in parallel. Also, in the semiconductor device of WO 2020/054806 A, the two configurations of JP 2023-167403 A are connected in parallel, and similarly, voltage drops are not made uniform using inductances in sections where the main current flows.

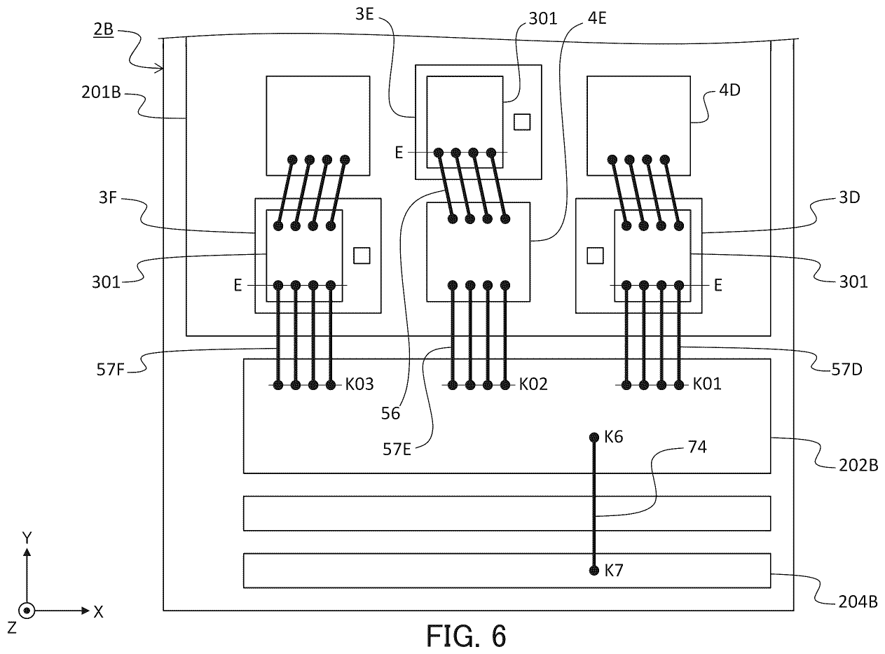

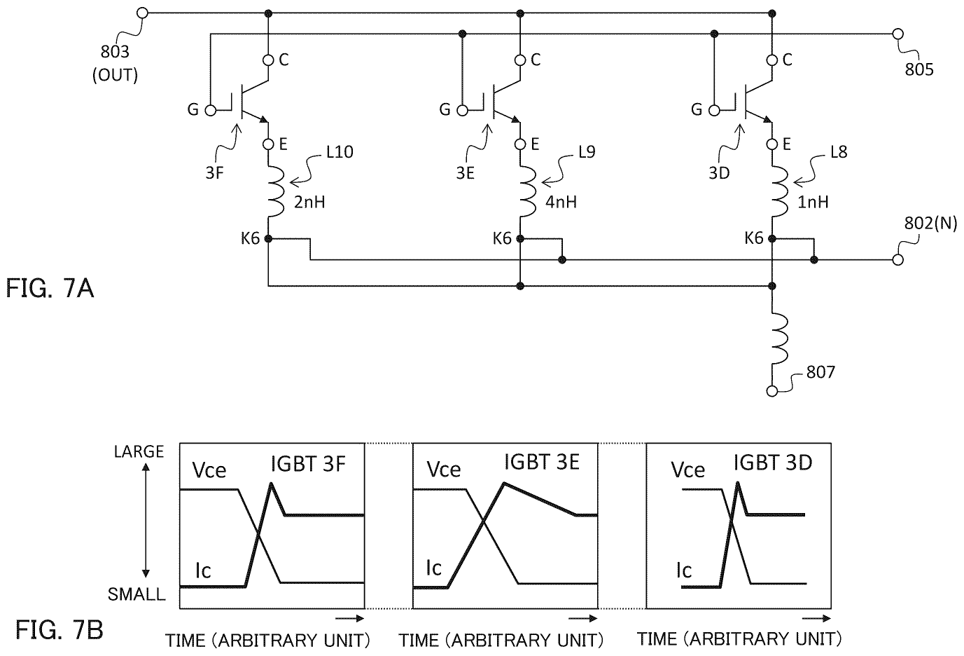

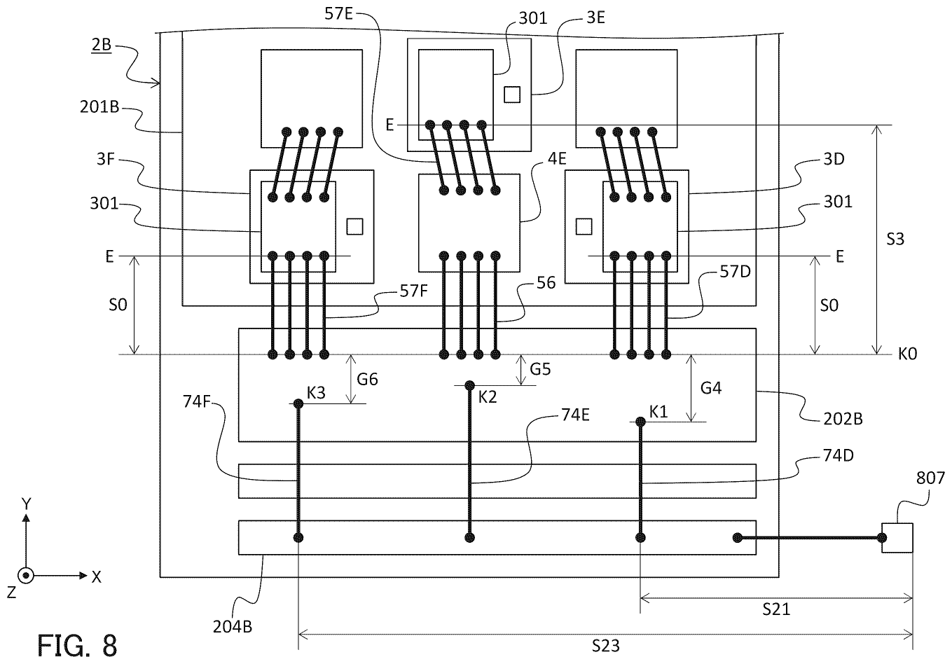

FIG. 6 is a partially enlarged plan view for illustrating a conventional example of the auxiliary emitter wiring in the semiconductor module in which a plurality of semiconductor elements is connected in parallel. FIG. 7A is an equivalent circuit diagram for illustrating an example of the inductance of the auxiliary emitter wiring in the semiconductor module of FIG. 6, and FIG. 7B is a graph illustrating an example of a switching operation in the semiconductor module of FIG. 6. FIG. 8 is a partially enlarged plan view for illustrating a modification of the semiconductor module according to the embodiment.

Similarly to the semiconductor module 1 of the present embodiment, three semiconductor elements (switching elements) 3D to 3F as illustrated in FIG. 6 are connected in parallel between the third main terminal 803 and the second main terminal 802 (sec FIG. 7A). The emitter electrode 301 of each of the semiconductor elements 3D to 3F disposed on the conductor pattern 201B of the wiring board 2 is connected to the conductor pattern 202B of the wiring board 2, and the emitter electrode 301 of each of the semiconductor elements 3D and 3F is directly connected to the conductor pattern 202B by each of the bonding wires 57D and 57F, whereas the emitter electrode 301 of the semiconductor element 3E is connected to the conductor pattern 202B through the anode electrode of the diode (semiconductor element) 4 connected in anti-parallel. Also, in the semiconductor module as illustrated in FIG. 6, the conductor pattern 202B and the conductor pattern 204B which is a part of the auxiliary emitter wiring and is connected to the control terminal (auxiliary emitter terminal) (not illustrated) are connected by one bonding wire 74. That is, the auxiliary emitter wiring of the semiconductor module as illustrated in FIG. 6 is similar to, for example, the auxiliary emitter wiring of the semiconductor device of JP 2023-167403 A.

When focusing on inductance, the auxiliary emitter wiring in the semiconductor module as illustrated in FIG. 6 may represented as the equivalent circuit diagram of FIG. 7A. In FIG. 7A, a white circle (○) with “E” corresponds to the connection point E between the emitter electrode 301 of the semiconductor elements 3D, 3E, and 3F and each of the bonding wires 57D, 56, and 57F as illustrated in FIG. 6. Also, connection point KK6 in FIG. 7A corresponds to connection point K6 of the bonding wire in FIG. 6.

In the semiconductor module as illustrated in FIG. 6, the length from the connection point E to the connection point K01 in the auxiliary emitter wiring for the semiconductor element 3D and the length from the connection point E to the connection point K03 in the auxiliary emitter wiring for the semiconductor element 3F are substantially the same. However, the length from the connection point E to the connection point K02 in the auxiliary emitter wiring for the semiconductor element 3E is longer than lengths between the connection points in the auxiliary emitter wiring for each of the semiconductor elements 3D and 3F. Also, as compared with the distance from the connection point K01 to the connection point K6 in the auxiliary emitter wiring with respect to the semiconductor element 3D, the distance from the connection point K02 to the connection point K6 in the auxiliary emitter wiring with respect to the semiconductor element 3E and the distance from the connection point K03 to the connection point K6 in the auxiliary emitter wiring with respect to the semiconductor element 3F become longer. In such a semiconductor module, as in inductances L8 to L10 illustrated in FIG. 7A, variations in the inductance in sections from the connection point E through which the main current flows in the auxiliary emitter wiring for each of the semiconductor elements 3D to 3F to the connection point K6 become even greater. That is, variations in the voltage drop of the auxiliary emitter wiring with respect to each of the semiconductor elements (switching elements) 3D to 3F become greater. In this case, as illustrated in FIG. 7B, there is a tendency for variations in the switching speed, the switching loss, and the like to become greater among the three semiconductor elements 3D to 3F connected in parallel. FIG. 7B schematically illustrates waveforms of the collector current Ic and the collector-emitter voltage Vce during the turn-on of the semiconductor elements 3D to 3F, which are associated with the switching speed and the switching loss.

On the other hand, in the semiconductor module 1 according to the present embodiment, for example, as illustrated in FIG. 8, the conductor pattern 202B and the conductor pattern 204 of the wiring board 2B are connected by separate bonding wires 74D to 74F for each of the emitter electrodes 301 of the three semiconductor elements 3D to 3F connected in parallel. At this time, as described above, the longer the auxiliary emitter wiring is, the shorter the wiring section common to the path of the main current in the auxiliary emitter wiring is, so that it is possible to reduce variations in voltage drops among the auxiliary emitter wiring for each of three semiconductor elements (switching elements) 3D to 3F connected in parallel, and it is possible to reduce variations in the switching speed, the switching loss, and the like among the semiconductor elements 3D to 3F. Also, as illustrated in FIG. 8, in a case where dimensions of the semiconductor element 3 which is a switching element and the semiconductor element 4 which is a diode element are different from each other in a plan view, by disposing the semiconductor element 3 and the semiconductor element 4 in a staggered manner, the semiconductor element 3 and the semiconductor element 4 may be densely disposed as compared with a case where the semiconductor element 3 and the semiconductor element 4 are disposed such that distances to the conductor pattern 202B are the same (see FIG. 3), which is advantageous for downsizing of the semiconductor module 1 and the like.

Note that the number of semiconductor elements (switching elements) 3 connected in parallel in the semiconductor module 1 is not limited to three described above, and may be two, or four or more. Also, the switching element is not limited to the IGBT element, and may be configured with, for example, a power metal oxide semiconductor field effect transistor (MOSFET), a bipolar junction transistor (BJT), or the like. In a case where the switching element is a power MOSFET, the auxiliary source wiring connected to a source electrode of the MOSFET is provided as a line corresponding to the auxiliary emitter wiring. Also, the diodes connected in anti-parallel to the switching element may be configured with, for example, a schottky barrier diode (SBD), a junction barrier schottky (JBS) diode, a merged PN schottky (MPS) diode, a PN diode, or the like. Also, the semiconductor module 1 may use a reverse conducting (RC)-IGBT element in which a function of a switching element and a function of a diode are integrated, instead of the semiconductor element 3 which is a switching element and the semiconductor element 4 which is a diode. Furthermore, the semiconductor module 1 may include a gate drive circuit 12 (sec FIG. 4) and the like.

In the bonding members 71 and 74 used as a part of the auxiliary emitter wiring in the semiconductor module 1, the position of the connection point on the conductor pattern 202 side through which the main current flows is not limited to a specific position as long as the influence of the potential of the emitter electrode 301 of the semiconductor element 3 associated with the bonding member is sufficiently larger than the influence of the potential of the emitter electrode 301 of other semiconductor elements (in other words, the influence of the potential of the emitter electrode 301 of other semiconductor elements become sufficiently small). Also, for example, the extending directions of the bonding members (bonding wires) 71 and 74 in the plan view may be directions different from the extending directions of the bonding members 53 and 57. Furthermore, the extending directions of the bonding wires 74D, 74E, and 74F in the plan view may not be the same. The bonding members 71 and 74 used as a part of the auxiliary emitter wiring in the semiconductor module I may be directly connected to control terminals (auxiliary emitter terminals) 806 and 807 provided in the case 8 without going through the conductor patterns of the wiring board 2.

Instead of bonding wires, metal plates such as copper plates may be used for some of the bonding members in the semiconductor module 1. For example, the bonding member 51 for connecting the first main terminal 801 and the conductor pattern 201A of the wiring board 2A, the bonding member 53 for connecting the emitter electrode of each of the semiconductor elements 3A to 3C and the conductor pattern 202A of the wiring board 2A, the bonding member 56 for connecting the emitter electrode of each of the semiconductor elements 3D to 3F and the conductor pattern 202B of the wiring board 2B, and the like may be metal plates referred to as leads, lead frames, and the like. The wiring board 2 in the semiconductor module 1 may be, for example, one in which the heat dissipation pattern 208 is omitted.

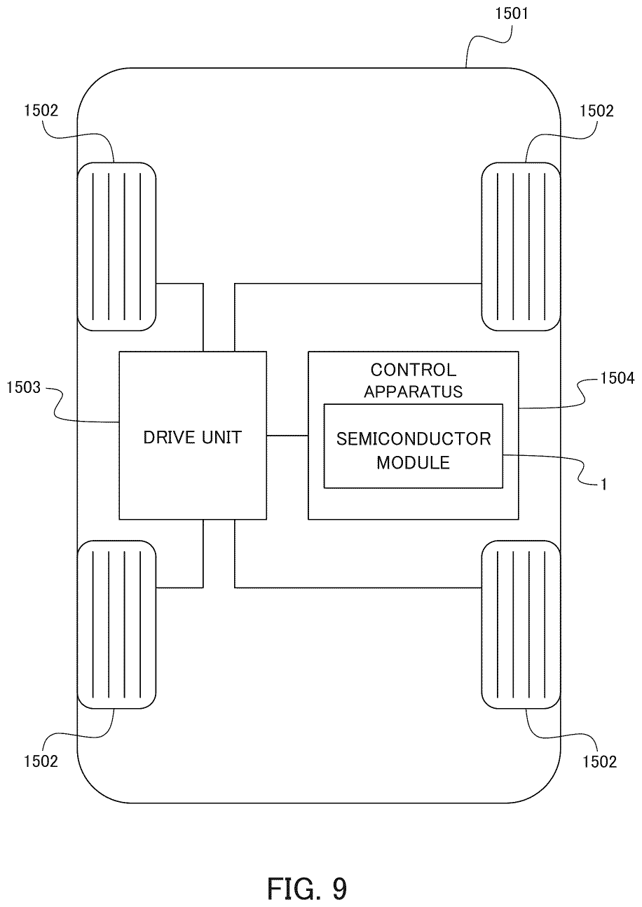

The semiconductor module 1 of the above embodiment is not limited to a specific application, but in particular, the semiconductor module 1 including the cooler 11 is suitable for use in a high-temperature environment. For example, the semiconductor module 1 of the above-described embodiment may be applied to a power conversion apparatus such as an inverter apparatus of an in-vehicle motor. A vehicle to which the semiconductor module 1 according to the present invention is applied is described with reference to FIG. 9.

FIG. 9 is a schematic plan view for illustrating an example of a vehicle to which the semiconductor module according to the present invention is applied. A vehicle 1501 illustrated in FIG. 9 is configured with, for example, a four-wheeled vehicle including four wheels 1502. The vehicle 1501 may be, for example, an electric vehicle that drives wheels by a motor or the like, or a hybrid vehicle using power of an internal combustion engine in addition to the motor. Also, the vehicle to which the semiconductor module 1 is applied is not limited to a four-wheeled vehicle, and may be a two-wheeled vehicle, a railway vehicle, or the like.

The vehicle 1501 includes a drive unit 1503 that applies power to the wheels 1502 and a control apparatus 1504 that controls the drive unit 1503. The drive unit 1503 may be configured with, for example, at least one of an engine, the motor, and a hybrid of the engine and the motor.

The control apparatus 1504 performs control (for example, power control) on the drive unit 1503. The control apparatus 1504 has the semiconductor module 1 including the cooler 11 of the above-described embodiment. The semiconductor module 1 may be configured to perform power control on the drive unit 1503.

The semiconductor module 1 of the above-described embodiment may be applied to, for example, an industrial power conversion apparatus such as an inverter apparatus that drives a motor of an elevator, an escalator, an air conditioning system of a building, or the like. Also, the circuit formed in the semiconductor module 1 is not limited to the half-bridge inverter circuit as illustrated in FIG. 4. The circuit formed in the semiconductor module 1 may have, for example, only an upper arm (circuit portion between the main terminal 801 and the main terminal 803) or a lower arm (circuit portion between the main terminal 803 and the main terminal 802) in the half-bridge circuit of FIG. 4, or may have a plurality of (for example, three) half-bridge inverter circuits. The circuit formed in the semiconductor module 1 may be a full-bridge inverter circuit. Furthermore, the circuit formed in the semiconductor module 1 is not limited to the power conversion circuit that converts direct current into alternating current, and may be another circuit.

Hereinafter, feature points in the above-described embodiment will be summarized.

The semiconductor module according to the above-described embodiment includes: a wiring board having a first conductor pattern and a second conductor pattern disposed on one surface of an insulating substrate; a plurality of semiconductor elements disposed on the first conductor pattern of the wiring board; a first bonding member for connecting each of the first main electrodes of the plurality of semiconductor elements to the first conductor pattern; a second bonding member for connecting each of the second main electrodes of the plurality of semiconductor elements to the second conductor pattern; a first terminal connected to the first main electrodes of the plurality of semiconductor elements through the first conductor pattern, through which a main current flows; a second terminal connected to the second main electrodes of the plurality of semiconductor elements through the second conductor pattern, through which a main current flows; and a third terminal connected to the second conductor pattern through a third bonding member. Each of the plurality of semiconductor elements includes a switching element that controls a current flowing between the first main electrode and the second main electrode, the third bonding member includes a plurality of bonding members associated with each of the plurality of semiconductor elements, and the distance from a connection point of the plurality of bonding members on the second conductor pattern to a connection point of the second bonding member varies depending on the distance from a predetermined position in the third terminal to a connection point with the second bonding member in the second main electrode of the plurality of semiconductor elements.

In the semiconductor module according to the above embodiment, the plurality of semiconductor elements include a first semiconductor element and a second semiconductor element, and in a case where the distance from the predetermined position in the third terminal to a connection point with the second bonding member in the second main electrode of the first semiconductor element is longer than the distance from the predetermined position in the third terminal to a connection point with the second bonding member in the second main electrode of the second semiconductor element, the distance from a connection point of a bonding member associated with the first semiconductor element in the third bonding member to a connection point of the second bonding member connected to the second main electrode of the first semiconductor element on the second conductor pattern is shorter than the distance from a connection point of a bonding member associated with the second semiconductor element in the third bonding member to a connection point of the second bonding member connected to the second main electrode of the second semiconductor element.

In the semiconductor module according to the above embodiment, the third terminal is connected to a control circuit that generates a control signal to be applied to the control electrodes of the plurality of semiconductor elements.

In the semiconductor module according to the above embodiment, each of the plurality of semiconductor elements includes the switching element and a diode connected in anti-parallel to the switching element.

The semiconductor module according to the above embodiment further includes a plurality of second semiconductor elements connected to each of the plurality of semiconductor elements, and each of the plurality of second semiconductor elements includes a diode connected in anti-parallel to the switching element in each of the plurality of semiconductor elements.

In the semiconductor module according to the above embodiment, the second bonding member includes a bonding member that connects, through an electrode of one semiconductor element of the plurality of second semiconductor elements, the second main electrode of the semiconductor element and the second conductor pattern.

In the semiconductor module according to the above embodiment, the plurality of semiconductor elements is disposed on the first conductor pattern such that lengths from a connection point with the second main electrode in the second bonding member to a connection point with the second conductor pattern are substantially the same.

In the semiconductor module according to the above embodiment, the first bonding member is a bonding material, and the second bonding member and the third bonding member are bonding wires.

In the semiconductor module according to the above embodiment, the switching element is an insulated gate bipolar transistor (IGBT) element, the first main electrode is a collector electrode of the IGBT element, and the second main electrode is an emitter electrode of the IGBT element.

In the semiconductor module according to the above embodiment, the plurality of semiconductor elements is disposed such that distances to the second conductor pattern are the same.

The semiconductor module according to the above embodiment further includes a cooler which is disposed in a direction opposite to a direction in which the semiconductor element is disposed in the wiring board and which is connected to the wiring board.

The vehicle according to the above-described embodiment includes the semiconductor module according to the above embodiment.

Note that the present invention is not limited to the above-described embodiments, and various changes, substitutions, and modifications may be made without departing from the spirit of the technical idea. Further, when the technical idea may be implemented in another method by the progress of the technology or another derived technology, the technical idea may be carried out by using the method thereof. Therefore, the claims cover all implementations that may be included within the scope of the technical idea.

As described above, the present invention has an effect that variations in switching operation among a plurality of switching elements connected in parallel in a semiconductor module may be reduced, and a decrease in operation reliability of the semiconductor module due to variations in heat generation of the switching elements may be suppressed, and is particularly useful for an industrial or on-vehicle semiconductor module used as a power conversion apparatus.

What is claimed is:

1. A semiconductor module comprising:
a wiring board, having:
an insulating substrate, and
a first conductor pattern and a second conductor pattern disposed on a surface of the insulating substrate;
a plurality of semiconductor elements disposed on the first conductor pattern of the wiring board, each having a switching element including a first main electrode and a second main electrode, and controlling a current flowing between the first main electrode and the second main electrode;
a first bonding member connecting each of the first main electrodes of the plurality of semiconductor elements to the first conductor pattern;
a second bonding member connecting each of the second main electrodes of the plurality of semiconductor elements to the second conductor pattern;
a first terminal connected to the first main electrodes of the plurality of semiconductor elements through the first conductor pattern;
a second terminal connected to the second main electrodes of the plurality of semiconductor elements through the second conductor pattern; and
a third terminal connected to the second conductor pattern through a plurality of third bonding members respectively corresponding to the plurality of semiconductor elements, wherein
a distance between a connection point of each of the plurality of third bonding members to the second conductor pattern and a connection point of the second bonding member to the second conductor pattern varies depending on a distance between a predetermined position in the third terminal and a connection point of the second bonding member to the second main electrode of each of the plurality of semiconductor elements.

2. The semiconductor module according to claim 1, wherein
the plurality of semiconductor elements includes a first semiconductor element and a second semiconductor element,
the plurality of third bonding members includes a first third bonding member and a second third bonding member corresponding to the first semiconductor element and the second semiconductor element, respectively,
the distance between the predetermined position in the third terminal and the connection point of the second bonding member to the second main electrode of the first semiconductor element is longer than the distance between the predetermined position in the third terminal and the connection point of the second bonding member to the second main electrode of the second semiconductor element, and
the distance between the connection point of the first third bonding member to the second conductor pattern and the connection point of the second bonding member to the second main electrode of the first semiconductor element is shorter than the distance between the connection point of the second third bonding member to the second conductor pattern and the connection point of the second bonding member to the second main electrode of the second semiconductor element.

3. The semiconductor module according to claim 1, wherein
the third terminal is configured to receive, from a control circuit, a control signal, and to apply the control signal to each of the plurality of switching elements.

4. The semiconductor module according to claim 3, wherein
each of the plurality of semiconductor elements is a semiconductor chip that includes the switching element and a diode connected in anti-parallel to the switching element.

5. The semiconductor module according to claim 3, further comprising:
a plurality of second semiconductor elements connected to each of the plurality of semiconductor elements,
wherein each of the plurality of second semiconductor elements includes:
a diode connected in anti-parallel to the switching element.

6. The semiconductor module according to claim 5, wherein
each of the second semiconductor elements has an electrode, and
the second bonding member includes a plurality of bonding members that respectively connects, the plurality of electrodes, the second main electrodes of the semiconductor elements of the plurality of second semiconductor elements and the second conductor pattern.

7. The semiconductor module according to claim 1, wherein the plurality of semiconductor elements is disposed on the first conductor pattern such that distances respectively between connection points of the second bonding member to the second main electrodes of the plurality of semiconductor elements and connection points of the second bonding member to the second conductor pattern are substantially the same.

8. The semiconductor module according to claim 1, wherein
the first bonding member is a bonding material, and
each of the second bonding member and the third bonding members is a bonding wire.

9. The semiconductor module according to claim 1, wherein
the switching element is an insulated gate bipolar transistor (IGBT) element,
the first main electrode is a collector electrode of the IGBT element, and
the second main electrode is an emitter electrode of the IGBT element.

10. The semiconductor module according to claim 1, wherein the plurality of semiconductor elements is disposed such that distances respectively between the plurality of semiconductor elements and the second conductor pattern are the same.

11. The semiconductor module according to claim 1, further comprising:
a cooler connected to the wiring board, the cooler and the plurality of semiconductor elements being disposed on opposite sides of the wiring board.

12. A vehicle comprising the semiconductor module according to claim 10.
